(19) United States
(12) Patent Application Publication
(10) Pub. No.: US 2026/0342312 A1
(43) Pub. Date: Oct. 29, 2026

(54) TUNABLE SURFACE ACOUSTIC WAVE RESONATOR

(71) Applicant: Murata Manufacturing Co., Ltd., Nagaokakyo-Shi, Kyoto (JP)

(72) Inventor: W. Richard SMITH, SAN DIEGO, CA (US)

(21) Appl. No.: 19/123,371

(22) PCT Filed: Sep. 27, 2023
(86) PCT No.: PCT/US2023/075220

§ 371 Date: Apr. 22, 2025

Related U.S. Application Data
(60) Provisional application No. 63/381,469, filed on Oct. 28, 2022.

(51) Int. Cl. H03H 9/25; H03H 9/02; H03H 9/64

(52) U.S. Cl. CPC H03H 9/25; H03H 9/6403; H03H 9/6483; H03H 2009/02165

(57) ABSTRACT

Tunable surface acoustic wave resonators and bandpass filters made from these surface acoustic wave resonators are capable of being tuned by up to 20% within the GHz frequency range. The tunable surface acoustic wave resonators include a high-acoustic-velocity substrate (20), a piezoelectric layer (40), a resonator interdigital transducer (80), reflectors (90), and a tuning electroacoustic transducer (100). The tuning electroacoustic transducer includes a planar metallic structure and a variable reactive element (110) electrically coupled across the planar metallic structure. The variable reactive element is connected across the planar metallic structure of the tuning electroacoustic transducer thus adding or subtracting to the capacitance of the planar metallic structure and subsequently changing the velocity and wavelength of the resulting acoustic wave on or through the piezoelectric layer, thereby controllably changing the resonant frequency and tuning the passband of filters comprising these resonators.

### CROSS REFERENCE TO RELATED APPLICATIONS

The present application claims priority to U.S. Provisional Application No. 63/381,469 filed on Oct. 28, 2022, the content of which is incorporated herein by reference in its entirety.

### FIELD

The present disclosure relates to a tunable surface acoustic wave resonator and to filters comprising such resonators.

### BACKGROUND

Surface acoustic wave devices comprising a plurality of surface acoustic wave resonators are widely used as filters in the GHz frequency range in cellular phones. These acoustic wave devices usually include a substrate, a piezoelectric layer with an interdigital transducer (IDT) at an interface of the piezoelectric layer, and in some cases a low acoustic velocity intermediate layer between the substrate and piezoelectric layer. When an RF signal is applied across the IDT, the internal stress within the lattice of the piezoelectric layer produces a surface acoustic wave propagating in two opposed directions away from the IDT. Reflectors flanking the IDT confine the wave in the region near the IDT, resulting in a sharp electrical resonance seen at the IDT terminals, specifically a low impedance at a “resonant” frequency and a high impedance at a slightly higher “anti-resonant” frequency. Unwanted resonant-frequency shifts in the resonators and concomitant shifts of GHz filter passbands can occur from ageing, temperature variations, and manufacturing variations. It is important to eliminate or at least minimize unwanted frequency shifts exhibited by existing acoustic wave filters to maintain acceptable performance within the GHz frequency ranges. Therefore, there is a need for further improving the frequency performance of these type of acoustic wave devices to minimize or correct unwanted frequency shifts.

### SUMMARY

According to a first embodiment, a tunable surface acoustic wave resonator is provided, comprising: a high-acoustic-velocity substrate; an intermediate layer on the high-acoustic-velocity substrate; a piezoelectric layer on the intermediate layer, a combination of the piezoelectric layer and the intermediate layer forming a buried planar surface as an interface between the intermediate layer and the piezoelectric layer, the piezoelectric layer having an exposed planar surface opposite the buried planar surface; a resonator interdigital transducer (IDT) on one planar surface among the buried planar surface and the exposed planar surface, the resonator IDT comprising: a resonator IDT RF first terminal, a first busbar coupled to the resonator IDT RF first terminal, first fingers coupled to the busbar, the first fingers being parallel to each other and being separated apart from each other by intervals approximating an acoustic wavelength near the resonant frequency; a resonator IDT RF second terminal, a second busbar coupled to the resonator IDT RF second terminal, and second fingers coupled to the second busbar, the second fingers being parallel to each other and being separated apart from each other by intervals approximating the acoustic wavelength near the resonant frequency, wherein the first fingers and the second fingers are interdigitated together and are separated apart from each other by intervals approximating one-half of the acoustic wavelength near the resonant frequency; reflectors on the one planar surface, the reflectors flanking the resonator IDT on the one planar surface, the reflectors comprising: metal stripes parallel to each other and separated from each other by intervals approximating one-half of the acoustic wavelength near the resonant frequency, the metal stripes being parallel to the first fingers and the second fingers of the resonator IDT, and metal crossbars attached to the metal stripes, the metal crossbars being perpendicular to the metal stripes; and a tuning electroacoustic transducer on the other planar surface among the buried planar surface and the exposed planar surface, the tuning electroacoustic transducer including: a tuning electroacoustic transducer primary terminal, a tuning electroacoustic transducer secondary terminal, a planar metallic structure between the primary terminal and the secondary terminal, the planar metallic structure having a placement on the other planar surface overlapping or underlying at least the resonator IDT on the one planar surface, and a variable reactive element electrically coupled across the tuning electroacoustic transducer primary and secondary terminals, wherein the resonator IDT and the reflectors are configured to form a resonant chamber within the piezoelectric layer when an RF input signal having a resonant center frequency is applied across the resonator IDT, whereby acoustic waves at the acoustic wavelength emanate away from the resonator IDT through the piezoelectric layer, and wherein tuning of the variable reactive element results in tuning the resonant center frequency.

According to a second embodiment, a tunable surface acoustic wave resonator is provided, comprising: a substrate; an intermediate layer on the substrate; a piezoelectric layer on the intermediate layer, a combination of the piezoelectric layer and the intermediate layer forming a buried planar surface as an interface between the intermediate layer and the piezoelectric layer, the piezoelectric layer having an exposed planar surface opposite the buried planar surface; a resonator on one planar surface among the buried planar surface and the exposed planar surface, the resonator comprising a resonator RF first terminal and a resonator IDT RF second terminal; reflectors on the one planar surface, the reflectors flanking the resonator on the one planar surface; a tuning electroacoustic transducer located, at least in part, on the other planar surface among the buried planar surface and the exposed planar surface, the tuning electroacoustic transducer including: a tuning electroacoustic transducer primary terminal, a tuning electroacoustic transducer secondary terminal, a planar metallic structure between the primary terminal and the secondary terminal, the planar metallic structure having a placement on the other planar surface overlapping or underlying at least the resonator on the one planar surface, and a variable reactive element electrically coupled across the tuning electroacoustic transducer primary and secondary terminals, wherein the resonator and the reflectors are configured to form a resonant chamber within the piezoelectric layer that has a characteristic resonant center frequency when an RF input signal is applied across the resonator, whereby acoustic waves emanate away from the resonator through the piezoelectric layer, and wherein tuning of the variable reactive element results in tuning the resonant center frequency.

Further embodiments of the disclosure will be presented in the description, claims and drawings of the present application.

### BRIEF DESCRIPTION OF THE DRAWINGS

The present disclosure is best understood from the following detailed description when read in conjunction with the accompanying figures. Various features may not be drawn to scale and used for illustration purposes only.

FIG. 1 depicts a perpendicular cross-sectional view (partially in block-diagram form) of a tunable surface acoustic wave resonator according to an embodiment of the present disclosure.

FIG. 2 depicts a plan view of a resonator interdigital transducer (IDT) and reflectors at the buried planar surface of the piezoelectric layer of the resonator of FIG. 1.

FIG. 3 depicts a plan view of a planar metallic structure of a tuning electroacoustic transducer on the exposed planar surface of the piezoelectric layer of the resonator of FIG. 1.

FIG. 4 depicts the planar metallic structure of the tuning electroacoustic transducer on the exposed planar surface of the piezoelectric layer coupled across a variable reactive element such as a capacitor.

FIG. 5 depicts a stylized cross-sectional view of the tunable surface acoustic wave resonator of FIG. 1 showing a planar metallic structure of the tuning electroacoustic transducer above the resonator IDT.

FIG. 6 depicts a stylized 3D transparent view of the tunable surface acoustic wave resonator having the tuning electroacoustic transducer at the buried planar surface and having the IDT resonator and the reflectors at the exposed planar surface of the piezoelectric layer.

FIG. 7 depicts a plurality of tunable surface acoustic wave resonators interconnected together to form an electronic ladder-type bandpass filter with series-arm resonators and shunt-arm resonators.

FIG. 8 depicts magnitude of the electrical terminal impedance (|Z|) as a function of GHz frequency for two different acoustic resonators that are built to resonate at slightly different frequencies, also indicating the location of a filter pass band that can be created by using these resonators in a ladder circuit.

FIG. 9 shows a notional transfer function (S21, dB) curve as a function of frequency for a signal transmitted through a bandpass filter.

FIG. 10 depicts an exemplary circuit scheme for a digitally controlled variable capacitive element circuit.

FIG. 11 depicts an exemplary circuit scheme for a digitally controlled variable inductive element circuit.

FIG. 12 depicts graphic directions of how to tune a surface acoustic wave resonator, i.e. change/shift its resonant frequency, by changing the variable reactance element connected to the tuning electroacoustic transducer.

FIG. 13 depicts multiple curves of susceptance (B) presenting at the resonator IDT terminals as a function of frequency, corresponding to different values of a variable capacitor connected across the tuning IDT.

FIG. 14 depicts multiple curves of susceptance (B) presenting at the resonator IDT terminals as a function of frequency, corresponding to different values of a variable inductor connected across the tuning IDT.

The same reference numerals refer to the same parts throughout the various figures.

### DETAILED DESCRIPTION

Throughout this description, the embodiments and examples shown should be considered as exemplary, rather than as limitations on the teachings of the present disclosure.

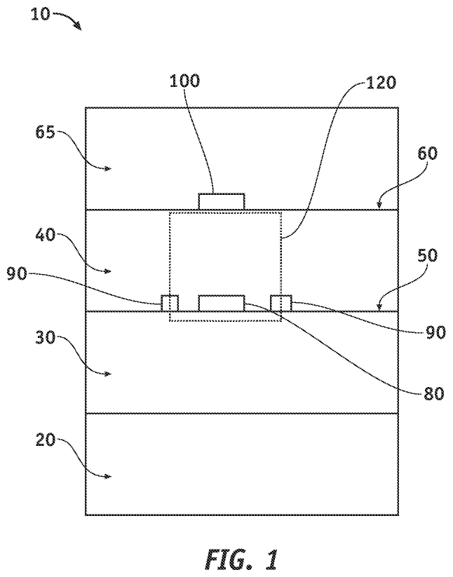

FIG. 1 shows a cross-sectional view of one embodiment of a tunable surface acoustic wave resonator (10) according to the present disclosure. The tunable surface acoustic wave resonator is shown to include a substrate layer (20), e.g., a high-acoustic velocity substrate layer, an intermediate layer (30) having a buried planar surface (50), and a piezoelectric layer (40) having an exposed planar surface (60). Planar surface (50) of the intermediate layer (30) is buried in view of the piezoelectric layer (40) lying above the intermediate layer (30), while planar surface (60) is exposed, for example, to a gaseous phase (65). The gaseous phase is preferably ambient air but can also be any gaseous phase such as helium, neon, krypton and/or other gases.

Also shown in the figure are an interdigital transducer (80) (called resonator IDT throughout the present disclosure) and reflectors (90) flanking the resonator IDT (80), all of which are positioned on the buried planar surface (50). FIG. 1 further shows a tuning electroacoustic transducer (100) on the exposed planar surface (60) about the same size and positioning as the resonator IDT. The relative sizing of the tuning electroacoustic transducer can be larger than the resonator IDT. The tuning electroacoustic transducer can also be flanked by reflectors.

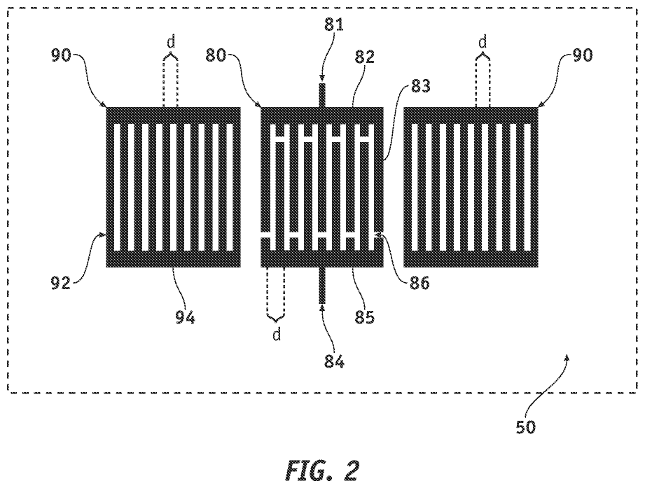

The tunable surface acoustic wave resonator (10) is configured to form, in use, a resonant chamber (120), wherein the energy of the wave is essentially confined-vertically by the inherent properties of the surface wave mode and horizontally by reflectors (90). The resonant chamber (120) is shown within the piezoelectric layer and is in contact with the resonator IDT (80) and the tuning electroacoustic transducer (100). The resonator IDT (80), the reflectors (90), and the tuning electroacoustic transducer (100) are configured to enable control of the frequency at which a sharp electrical resonance and anti-resonance are present in the impedance seen at the terminals (81,84) of the resonator IDT (80), as explained in better detail in the following figures. Bandpass filters can be constructed by connecting the resonator IDT terminals (81,84 in FIG. 2) of a plurality of resonators (50) into an electrical network such as a ladder or lattice circuit. For obtaining desired bandpass filter performance, a relevant performance feature of resonators is the impedance realized across terminals (81,84) as a function of frequency and specifically obtaining desired frequencies of resonance (lowest impedance) and anti-resonance (highest impedance).

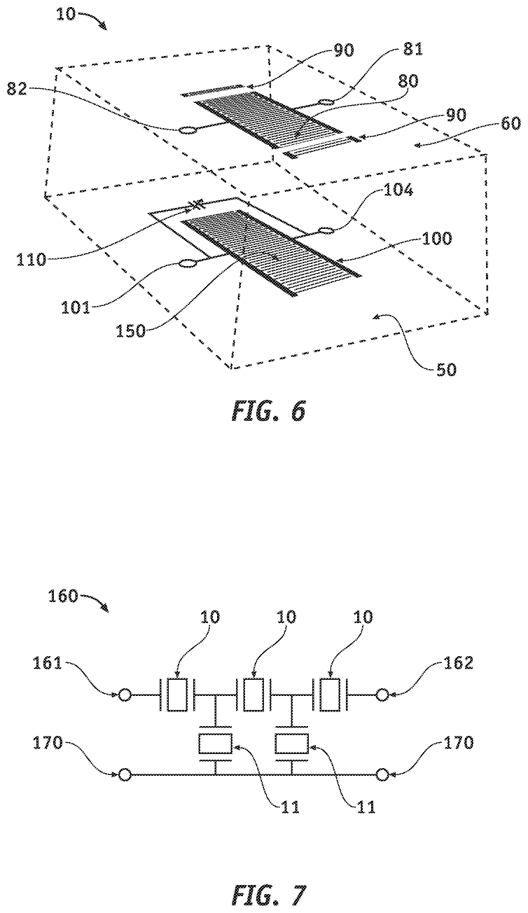

FIG. 1 shows the resonator IDT (80) and reflectors (90) at the buried planar surface (50) and shows the tuning electroacoustic transducer (100) at the exposed planar surface (60). Alternative embodiments are also possible, where the resonator IDT (80) and reflectors (90) are at the exposed planar surface (60) and the tuning electroacoustic transducer (100) is at the buried planar surface (50). In either embodiment (see also FIG. 6, later described), electrical signals applied to the resonator IDT and passive loads applied to the tuning IDT can interact with the acoustic wave via piezoelectric coupling, since both IDT's are in contact with the resonant chamber where the wave is substantially confined.

FIG. 2 shows a stylized and exemplary plan view of the resonator IDT (80) and reflectors (90), e.g., at the buried planar surface (50). The resonator IDT is shown to include a resonator IDT radio frequency (RF) first terminal (81) coupled to a resonator IDT first busbar (82) and to resonator IDT first fingers (83). The resonator IDT is also shown to include a resonator IDT RF second terminal (84) coupled to a resonator IDT second busbar (85) and to resonator IDT second fingers (86) .. In the embodiment shown in the figure, the first fingers (83) and the second fingers (86) are interdigitated together so that the distance between closest parallel electrodes is “d” and the distance between successive parallel electrodes of the same “finger set” (first or second) is 2d. The spacing between successive stripes of the reflectors (90) is also “d”. The resonant frequency at which the resonator IDT's impedance (across terminals (81,84)) reaches a minimum is fᵣ=v/2d, where v is the velocity of the acoustic wave, at which particular frequency “d” is equal to one-half acoustic wavelength. Therefore, the resonant frequency fᵣ can be changed (and the entire impedance-versus-frequency curve of the resonator shifted in frequency) if the acoustic velocity can be changed. The spacing d is equal to a half-wavelength at the resonant frequency fr=v/2d and approximately equal at nearby frequencies around the filter passband. The number of each first and second fingers can range from one to over twenty, if desired or required by the various applications of the resonator. Furthermore, the capacitance and therefore the impedance level of the resonator IDT can be adjusted to a convenient value by varying parameters such as the length and width of the various first and second fingers.

With continued reference to FIG. 2, the reflectors (90) are shown flanking the IDT resonator (80) on the buried planar surface (50) and are configured to reflect the acoustic wave generated by the resonator IDT (80), confining it to the resonant chamber most efficiently at the resonant frequency fᵣ=v/2d. The reflectors (90) include metal stripes (92) and metal crossbars (94). The metal stripes (92) are parallel to each other and are separated apart from each other by a distance “d” which is equal to one-half the wavelength of the acoustic wave at the resonant frequency fᵣ and approximately equal at nearby frequencies around the filter passband. The number of metal stripes in the reflectors may range from one to well over five in number, if desired or required. The metal stripes (92) of the reflectors (90) are also parallel to the first and second fingers (83, 86). In the embodiment of the figure, the metal crossbars (94) are attached and perpendicular to the metal stripes (92).

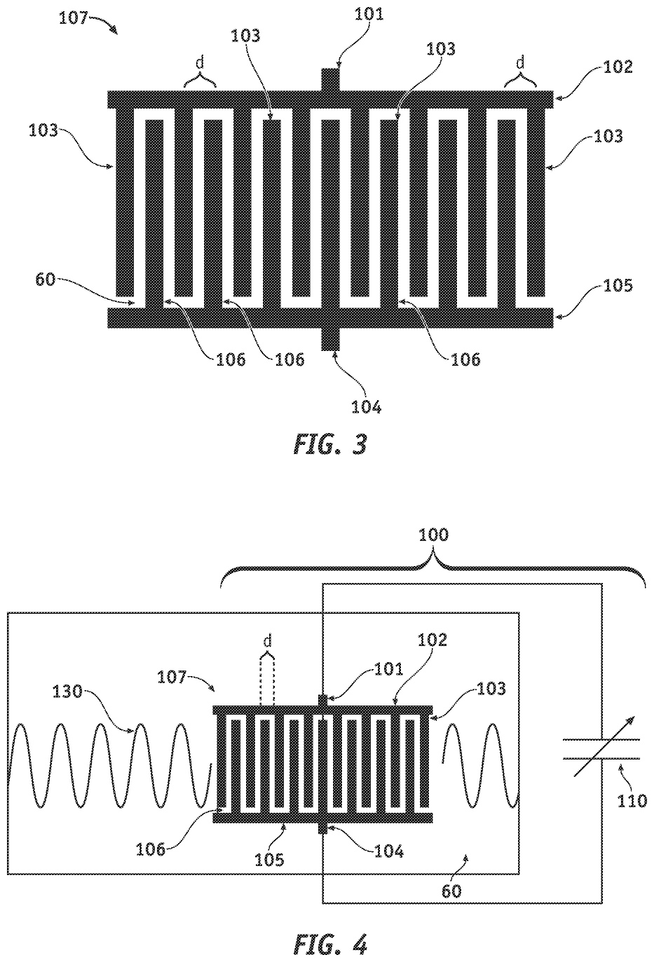

FIG. 3 shows a plan view of an exemplary planar metallic structure (107) of the tuning electroacoustic transducer in an exemplary interdigital transducer (IDT) configuration. The planar metallic structure (107) is located, for example, on the exposed planar surface (60) of the piezoelectric layer (40). In the embodiment shown in the figure, the planar metallic structure (107) includes a first tuning terminal (101), a first tuning busbar (102), first tuning fingers (103), a second tuning terminal (104), a second tuning busbar (105); and second tuning fingers (106). The first tuning terminal (101) is coupled to the first tuning busbar (102). The first tuning busbar (102) is coupled to the first tuning fingers (103). The first tuning fingers (103) and second tuning fingers (106) are interdigitated and are parallel with respect to each other such that the distance between adjacent metal fingers is “d” and the distance between successive fingers of the same finger set (first or second) is 2d. This results in maximum interaction with the acoustic wave at or near the same resonant frequency as that of the resonator IDT, namely, fr=v/2d. Coupling of the first tuning terminal (101) and the second tuning terminal (102), via a passive electric load connected across them, will be discussed with reference to the next figure.

FIG. 4 depicts a tuning electroacoustic transducer (100) including the planar metallic structure (107) previously discussed in FIG. 3 coupled across a variable reactive element (110), e.g., a variable capacitor. Although the figure shows the IDT configuration previously discussed in FIG. 3, other configurations are also possible. For example, the planar metallic structure (107) might be as simply designed as two parallel metallic lines, each coupled to opposing terminals of the variable reactive element (110). Additionally, although FIG. 4 shows a variable capacitor, the person skilled in the art will understand, upon reading of the present disclosure, that any variable reactive element can be adopted, e.g., a variable inductor, or an arrangement including a plurality of variable reactive elements.

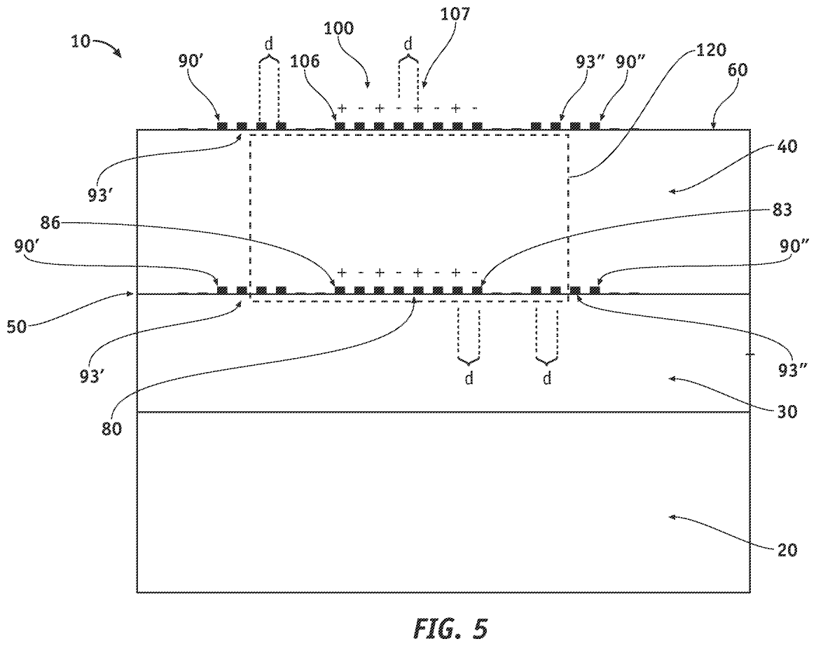

FIG. 5 depicts a cross-sectional view of the tunable surface acoustic wave resonator (10) of FIG. 1 showing the planar metallic structure (107) of the tuning electroacoustic transducer (100) on the exposed planar surface (60) of the piezoelectric layer (40). Directly underneath the planar metallic structure (107) of the tuning electroacoustic transducer (100) is the resonator IDT (80) flanked by a first reflector (90′) and a second reflector (90″). Along the buried planar surface (50) between the piezoelectric layer (40) and the intermediate layer (30) are resonator IDT first and second fingers (83, 86) directly underneath the first and second tuning fingers (103, 106) of the tuning electroacoustic transducer (100) on the exposed planar surface (60). Underneath the intermediate layer (30) is a high-acoustic-velocity substrate (20). Any number of embodiment variations are possible, such as the tuning electroacoustic transducer and the resonator IDT are substantially equal in extent and the tuning electroacoustic transducer is, similarly to the resonator IDT, flanked by reflectors (as shown in FIG. 5) to further confine the acoustic wave. Another variation is that the tuning electroacoustic transducer and the resonator IDT are substantially equal in extent and the tuning electroacoustic transducer has no reflectors (as previously shown in FIG. 1). Still another variation is that the tuning electroacoustic transducer (in a configuration without reflectors) extends beyond the area of the resonator IDT flanked by the reflectors so that the tuning electroacoustic transducer overlies both the resonator IDT and the reflectors flanking the resonator IDT.

The planar metallic structure (107) of the tuning electroacoustic transducer (100) functions as a means for changing the acoustic velocity (through piezoelectric coupling) by adjusting the type and value of the variable reactive element (110) connected to its terminals (101,104). Variable reactive element (110) (shown in FIG. 4) can be a capacitor, inductor, or combination of capacitor(s) and inductor(s). The (constant) native capacitance of planar metallic structure (107) (accruing via fringing electric fields between fingers (103) and (106)) also affects the acoustic velocity but can be considered as a constant increment to the “effective” value of variable reactive element (110) by being connected in parallel with it. The reactance (or, equivalently, susceptance) of the variable reactive element (110) can be controlled and set by a logic controller (not shown in the figure). Thus, the total reactive load connected across tuning transducer (107), hence the acoustic velocity v. and hence the resonant frequency of the resonator (50), namely fᵣ=v/2d, can all be varied in a programmable amount. It is to be understood that all portions of the wave, throughout all the volume of resonant chamber (120), (and specifically at the locations of both resonator and tuning IDT's) propagate together at the same velocity v.

Acoustic waves are produced at the resonator IDT when the RF signal passing through a filter applies an oscillating potential across the series of the interdigitated first and second fingers of the resonator IDT (i.e. across terminals (81,84). When such oscillating potential is applied across the resonator IDT, the first and second fingers create an oscillating electric field that fringes into the piezoelectric layer and, via piezoelectricity, produces an oscillating deformation of that layer, thereby launching acoustic waves propagating away from the first and second fingers of the resonator IDT and toward the reflectors (90). Because the confinement of the acoustic wave into the resonant chamber (120) is most efficient near the resonant frequency fᵣ=v/2d, (and inefficient at frequencies far removed from fr) the impedance presenting across terminals (81,84), as a function of frequency, exhibits a strong resonant/anti-resonant behavior that is needed for using the resonators in a filter circuit, as explained in more detail below.

FIG. 6 depicts a stylized 3D transparent (for the purpose of better understanding) perspective view of the tunable surface acoustic wave resonator (10) having the planar metallic structure (107) of the tuning electroacoustic transducer (100) at the buried or bottom planar surface (50) and having the IDT resonator (80) at the exposed or top planar surface (60) of the piezoelectric layer. The variable reactive element (110) is shown coupled to and across the planar metallic structure (107). In other words, the embodiment of FIG. 6 has the locations of the resonator and tuning IDTs interchanged in comparison to the embodiment shown in FIGS. 1 and 5.

The variable reactive element (110) can be located outside the tunable resonator structure shown in FIGS. 1 and 5. Any interconnection traces or structures such as flip-chip bump interconnections between tuning IDT (107) and variable reactive component (110) should be taken into account in determining and controlling the effective impedance that is applied across terminals (101,104) of the tuning IDT (107). It is preferable that the variable reactive element (110) not be in direct physical contact with any part of resonant chamber (120) in such a way as to disturb the acoustic wave.

With continued reference to FIG. 6, the planar metallic structure (107) is shown directly underneath the resonator IDT (80) with the reflectors (90) flanking the resonator IDT. Alternatively, if the positions of elements (100) and (80, 90) on the respective planar surfaces are swapped, the planar metallic structure (107) will be preferably directly above resonator IDT (90).

The resonator IDT (80) is separated from the tuning electroacoustic transducer (100) across the thickness of the piezoelectric layer, that thickness usually being a percentage of the wavelength of the acoustic wave. One preferred variant is that the piezoelectric layer is made of lithium tantalate and has a thickness of about a 30% fraction of the wavelength of the acoustic wave, i.e. about 60% of dimension “d”. Another preferred variant is that the intermediate layer comprises or is made of silicon dioxide and has a thickness of about a 33.7% fraction of the wavelength of the acoustic wave, i.e. about 67.4% of dimension “d”. A combination of such preferred variants make the resonators according to the present disclosure shown in FIGS. 1-6 suitable for use as an incredible high performance (IHP) surface acoustic wave (SAW) resonator in an IHP filter.

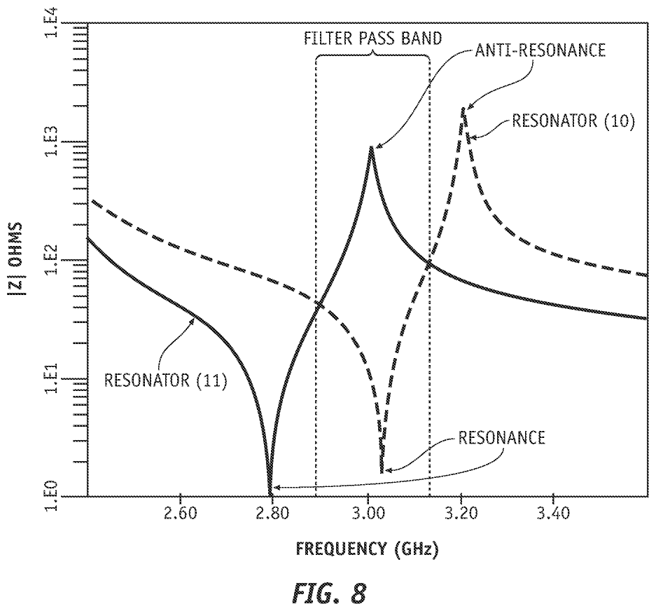

In the usual filtering application, multiple tunable surface acoustic wave resonators or IHP-SAW resonators in accordance with the present disclosure can be interconnected together to form a ladder type circuit to form a bandpass filter, as shown in FIG. 7, described below. By the piezoelectric process of converting the incident RF signal to a surface acoustic wave in the resonant chamber (120), these IHP-SAW resonators exhibit at terminals (81,84) an impedance-magnitude versus frequency curve of the shape shown in FIG. 8, also described below, having a minimum at the resonant frequency and a maximum at the anti-resonant frequency.

FIG. 7 shows a known arrangement of five tunable surface acoustic wave resonators coupled together into a ladder type tuning bandpass filter configuration (160). Each tunable surface acoustic wave resonator has its own variable reactive element in which each variable reactive element may be tuned independently. Preferably, each resonator is tuned by about the same amount so that the resultant filter shape stays relatively the same while the frequency range of the passband is tuned (shifted). Multiple series arms of the ladder type tuning bandpass filter can comprise any number of tunable surface acoustic wave resonators (10) coupled in series and coupled between a filter input terminal (161) and a filter output terminal (162). Shown are two other tunable surface acoustic wave resonators (11) in the shunt arms which are coupled to outputs of the series-arm resonators and coupled to a reference voltage (170), e.g., ground. Multiple shunt arms of the ladder type tunable bandpass filter can also comprise any number of tunable surface acoustic wave resonators.

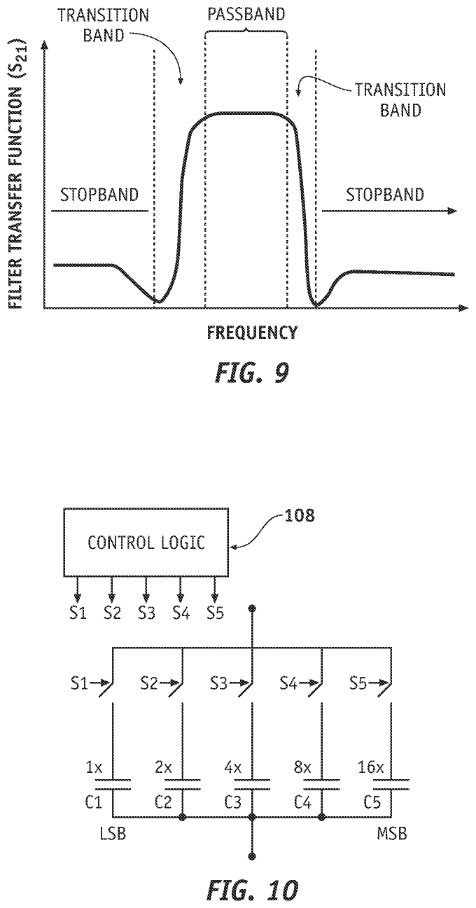

FIG. 8 shows a known plot of magnitude of the impedance (|Z|) accruing across resonator terminals (81,84) as a function of frequency for two different surface acoustic wave resonators designed with slightly different metal stripe spacings “d”, so that the resonant minimum impedance of resonator(s) (10) lines up at approximately the same frequency as the anti-resonant maximum impedance of resonator(s) (11) If resonators exhibiting the dashed curve in FIG. 8 are inserted as series-arm resonators (10) shown in FIG. 7, and resonators exhibiting the solid curve in FIG. 8 are inserted as shunt-arm resonators (11) of FIG. 7, there results a bandpass filter exhibiting a transfer function curve shown notionally in the following FIG. 9.

In particular, FIG. 9 is a notional graph of a bandpass filter transfer function (S21, on the vertical axis) as a function of frequency (horizontal axis) for an RF signal passing through the filter. A passband region is shown flanked by transition bands that then lead to stopbands around the transition bands. The narrowness of the transition band is desirable for achieving sharp boundaries between the passband and the stopbands.

With combined reference to FIGS. 7-9, the passband frequency range in FIG. 9 corresponds to where the series-arm resonators (10), in the circuit of FIG. 7, have a low impedance as shown as the dashed curve in the “passband” region labeled in FIG. 9. In the same frequency range, the shunt-arm resonators (11) have a high impedance, similar to an open circuit. As a consequence, in the frequency range of the passband, the series-arm resonators (10) of FIG. 7 act like short-circuits so the signal passes right through-considering that also the shunt-arm resonators (11) act like open circuits (solid curve in FIG. 8) so they do not short off the signal to ground. At stopband frequencies, either resonators (10) have high impedance and/or resonators (11) have low impedance, so the signal gets short-circuited to ground instead of passing through. The above general comments apply in case of a ladder topology, like the one shown in FIG. 7. The person skilled in the art will understand that other arrangements of resonators are also possible, such as lattice circuit topologies.

Turning now to the teachings of the embodiments in accordance with the present disclosure, in an embodiment, the planar metallic structure of the tuning electroacoustic transducer extends on one of the planar surfaces directly above the resonator IDT on the other one of the planar surfaces. In another embodiment, the planar metallic structure of the tuning electroacoustic transducer extends on one of the planar surfaces for an extension that encompasses (e.g., overlaps or underlies) and is larger than an extension of the resonator IDT on the other one of the planar surfaces.

The variable reactive element of the tuning electroacoustic transducer can be selected from any known type of variable capacitor and/or variable inductor scheme and combinations thereof. By way of example, the variable capacitor can be a digitally controlled variable capacitor or a varactor. Some types of varactors include PN-junction varactors or MOS varactors. MOS varactors are preferable due to their smaller dimensions, their lower DC bias requirements and their ability be optimized to have a high quality factor Q. Similarly, if a variable inductor is used, it can also be a digitally controlled variable inductor. Additionally, variable capacitors and inductors can be implemented through passive components, active components or combinations of both passive and active components.

One variant of the variable reactive element is that it is a bank of capacitors digitally controlled by switches, as described for example in PCT publication WO 2009/108391, which is incorporated herein by reference in its entirety.

FIG. 10 depicts an exemplary digitally controlled variable reactive element designed as a 5-branched 32-state digitally controlled variable capacitor having capacitors (C1 . . . C5) weighted according to, e.g., a binary scheme, going from a least significant bit LSB to a most significant bit MSB, driven by a bank of digital switches controlled by digital signals S1 . . . S5 output by a control logic block (108). The digital switches can be any known digital switches such as MOSFET switches and/or phase change material (PCM) switches. Each switch is configured to be in an ON state or an OFF state. If a specific switch (S1 . . . S5) is in the ON state, then contribution of its associated series capacitance is included in the total value of the variable capacitance. If, on the other hand, a specific switch is in the OFF state, then contribution of its series capacitance is excluded or minimized (to the small off-state capacitance of the switch) in the total value of the variable capacitance.

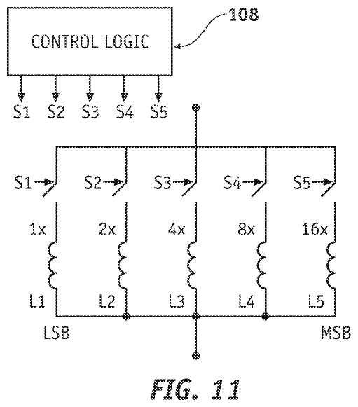

Similarly to the embodiment previously shown in FIG. 10, FIG. 11 depicts an exemplary digitally controlled variable reactive element designed as a 5-branched 32-state digitally controlled variable inductor having inductors (L1 . . . L5) instead of capacitors (C1 . . . C5).

Using tunable resonators according to several embodiments of the present disclosure, small tuning adjustments, differing independently as needed across all the resonators of the filter, can re-shape the passband to overcome variations in manufacturing, as well temperature changes or ageing changes during operation. Additionally, when using the tunable resonators as described in a filter, the same frequency shift can be applied to all resonators of the filter to tune the frequency of the filter passband to accommodate different signals across multiple bands or sub-bands used for multiple telecommunication channels. By extension of the two tuning scenarios just described, the different tunings applied across the resonators in a filter can contain both a “constant” frequency shift that is applied to all resonators to shift the frequency of the filter passband, plus an added “variable” frequency shift that is different among all the resonators, to adjust the shape of the passband/transition band/stopband as needed.

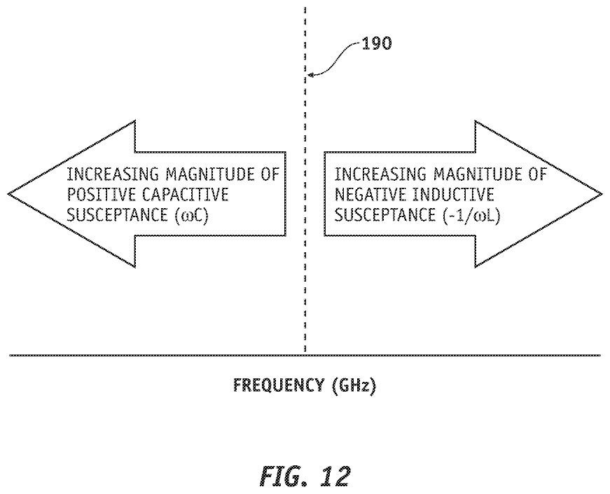

FIG. 12 broadly depicts how changes to the direction and magnitude of the reactance (or equivalent susceptance) added to a tunable surface acoustic wave resonator influence the direction of the frequency output of the tunable surface acoustic wave resonator, To tune the tunable surface acoustic wave resonator to frequencies lower than the native resonant frequency, then a capacitance, i.e. a negative reactance/positive susceptance) element (X=−1/ωC or B=+ωC), is loaded across the tuning electroacoustic transducer. In some embodiments, using a capacitor-only tunable surface acoustic wave resonator provides a tunable frequency range of about 2% downwards relative to the native resonant frequency (190). To tune the tunable surface acoustic wave resonator at frequencies higher than the native resonant frequency then an inductance, i.e. a positive reactance/negative susceptance (X=ωL or B=−1/ωL), is added. In some embodiments, using an inductor-only tunable surface acoustic wave resonator provides a tunable frequency range of about 20% upwards relative to the native resonant frequency.

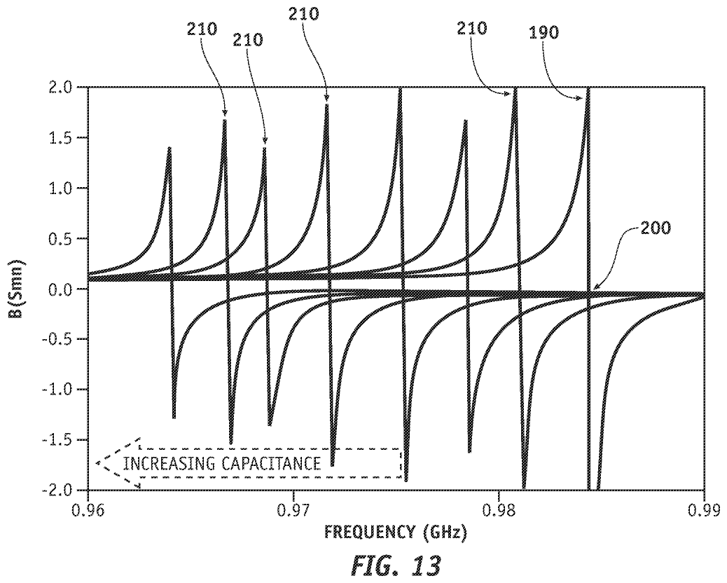

FIG. 13 depicts examples of the susceptance (B) versus frequency (GHz) response to various changes to the capacitive reactance of the variable reactive elements which are additionally loaded across terminals (101,104) of the tuning IDT of a tunable surface acoustic wave resonator. In these examples of FIG. 13, the variable reactive element is a variable capacitor. The curve (190) represents the case where the variable reactive element does not add any additional reactance load onto the tunable surface acoustic wave resonator. Accordingly, the resonant frequency of about 0.985 GHz exhibited in curve (190) is understood to be the native resonant frequency. This case is realized when the variable reactive element is in an open-circuit or disconnected configuration from the tuning electroacoustic transducer. As shown in the embodiment of the figure, increasing the capacitance load of the variable reactive element downwardly shifts the resulting resonant frequency by up to about a 2% range relative to the native resonant frequency of the tunable surface acoustic wave resonator. Accordingly, in some embodiments of the present disclosure, a plurality of tunable surface acoustic wave resonators with only variable capacitors as the variable reactive elements can be assembled to form a tunable bandpass filter having a tunable range of about 2%. As shown, increasing the capacitance load of the variable reactive element results in shifted resonant frequencies (210), i.e., tuned frequencies, that are lower than the native resonance frequency by about a 2% range. The total reactance (or, equivalently, susceptance) imposed on the first and second tuning fingers of the tuning electroacoustic transducer influences velocity “v” of the acoustic waves which results in a resonant frequency (v/2d) that is lower than the native resonance frequency. The resultant 2% tunable bandpass filter can realize several useful applications for correcting unwanted frequency shifts brought about by ageing filters, temperature variations, and manufacturing variations. The frequency corresponding to the susceptance zero intercept of any or the susceptance curves of FIG. 13 is referred to as the anti-resonant frequency (200).

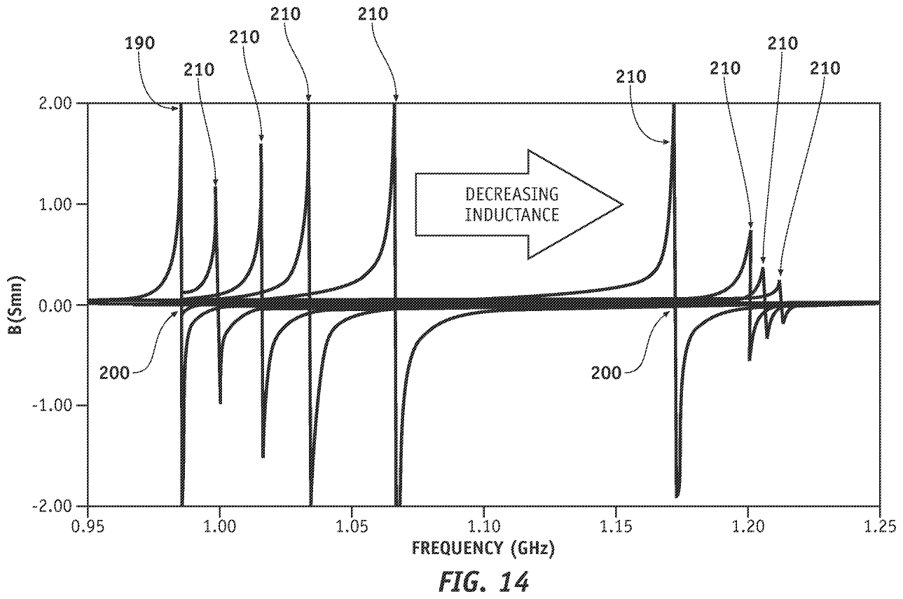

FIG. 14 depicts examples of the susceptance (B) versus frequency (GHz) response to various changes to the inductive reactance (or equivalent susceptance) of the variable reactive element which is loaded across a tunable surface acoustic wave resonator. In these examples the variable reactive element used is a variable inductor. Curve (190) exhibits the same “native” resonant frequency, about 0.985 GHz, as curve (190) of FIG. 13, as it again represents the case where the variable reactive element is in an open-circuit or disconnected configuration from the tuning electroacoustic transducer. As shown, magnitude (1/ωL) of the inductive susceptance (−1/ωL) (i.e. decreasing L) of the variable reactive element results in the shifting of the frequencies (210), that have higher frequencies than the native resonance frequency by about a 20% range. The total reactance (or, equivalently, susceptance) imposed on the first and second tuning fingers of the tuning electroacoustic transducer influences velocity “v” of the acoustic waves which results in a resonant frequency (v/2d) that is higher than the native resonance frequency. This 20% tuning range can be exploited in bandpass filter composed of a plurality of the tunable acoustic resonators discussed thus far. The 20% tuning range can realize several useful applications for correcting unwanted frequency shifts brought about by ageing filters, temperature variations, and manufacturing variations. The 20% tuning range is an amount robust enough to accommodate a wide variety of different frequency requirements (established signal bands) in 5G environments.

A tuning bandpass filter that implements resonators in accordance with the present disclosure can narrow frequencies ranges having steep transition bands along with being able to be swept, i.e., tuned, across a relatively broad 20% frequency range. To minimize the insertion loss of the tunable bandpass filter constructed from high-Q tunable surface acoustic wave resonators that utilize inductors as the variable reactive elements then active circuits may be required to support the inductors. For example, by combining variable capacitors with variable inductors in a digital stepping scheme one can potentially realize nearly a 22% shift in the center frequency of a tuning bandpass filter. In some cases, the peak value of the Q characteristics of the bandpass filter can exceed 3,000 in the GHz frequency range along the passband of the resultant bandpass filter made from a plurality of tunable surface acoustic wave resonators.

A number of embodiments of the invention have been described. It is to be understood that various modifications may be made without departing from the spirit and scope of the invention.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below.

1. A tunable surface acoustic wave resonator comprising:
a high-acoustic-velocity substrate;
an intermediate layer on the high-acoustic-velocity substrate;
a piezoelectric layer on the intermediate layer, a combination of the piezoelectric layer and the intermediate layer forming a buried planar surface as an interface between the intermediate layer and the piezoelectric layer, the piezoelectric layer having an exposed planar surface opposite the buried planar surface;
a resonator interdigital transducer (IDT) on one planar surface among the buried planar surface and the exposed planar surface, the resonator IDT comprising:
a resonator IDT RF first terminal,
a first busbar coupled to the resonator IDT RF first terminal,
first fingers coupled to the busbar, the first fingers being parallel to each other and being separated apart from each other by intervals approximating an acoustic wavelength near the resonant frequency;
a resonator IDT RF second terminal,
a second busbar coupled to the resonator IDT RF second terminal, and
second fingers coupled to the second busbar, the second fingers being parallel to each other and being separated apart from each other by intervals approximating the acoustic wavelength near the resonant frequency,
wherein the first fingers and the second fingers are interdigitated together and are separated apart from each other by intervals approximating one-half of the acoustic wavelength near the resonant frequency;
reflectors on the one planar surface, the reflectors flanking the resonator IDT on the one planar surface, the reflectors comprising:
metal stripes parallel to each other and separated from each other by intervals approximating one-half of the acoustic wavelength near the resonant frequency, the metal stripes being parallel to the first fingers and the second fingers of the resonator IDT, and
metal crossbars attached to the metal stripes, the metal crossbars being perpendicular to the metal stripes; and
a tuning electroacoustic transducer on the other planar surface among the buried planar surface and the exposed planar surface, the tuning electroacoustic transducer including:
a tuning electroacoustic transducer primary terminal,
a tuning electroacoustic transducer secondary terminal,
a planar metallic structure between the primary terminal and the secondary terminal, the planar metallic structure having a placement on the other planar surface overlapping or underlying at least the resonator IDT on the one planar surface, and
a variable reactive element electrically coupled across the tuning electroacoustic transducer primary and secondary terminals,
wherein the resonator IDT and the reflectors are configured to form a resonant chamber within the piezoelectric layer when an RF input signal having a resonant center frequency is applied across the resonator IDT, whereby acoustic waves at the acoustic wavelength emanate away from the resonator IDT through the piezoelectric layer, and
wherein tuning of the variable reactive element results in tuning the resonant center frequency.

2. The tunable surface acoustic wave resonator of claim 1, wherein the tuning of the variable reactive element comprises
changing a reactance of the variable reactive element added onto a native reactance of the plan metallic structure of the tuning electroacoustic transducer, resulting in changing a velocity and wavelength of the acoustic waves, such that the resonant frequency of the resonator is also changed.

3. The tunable surface acoustic wave resonator of claim 1, further comprising reflectors on the other planar surface, the reflectors flanking the tunable electroacoustic transducer on the other planar surface.

4. The tunable surface acoustic wave resonator of claim 3, wherein the planar metallic structure and the reflectors have a placement on the other planar surface overlapping or underlying the resonator IDT and the reflectors on the one planar surface.

5. The tunable surface acoustic wave resonator of claim 1, wherein the variable reactive element is a variable capacitor.

6. The tunable surface acoustic wave resonator of claim 5, wherein the variable capacitor is a digitally controlled variable capacitor.

7. The tunable surface acoustic wave resonator of claim 6, wherein the digitally controlled variable capacitor comprises a bank of weighted capacitors, each is series with a switch, the switch being configured to be in an ON state to include contribution to a total value of a variable capacitance of the capacitor in series with the switch or an OFF state to exclude or minimize contribution to the total value.

8. The tunable surface acoustic wave resonator of claim 7, wherein the switch is a MOSFET switch.

9. The tunable surface acoustic wave resonator of claim 7, wherein the switch is a PCM switch.

10. The tunable surface acoustic wave resonator of claim 5, wherein the variable capacitor is a varactor.

11. The tunable surface acoustic wave resonator of claim 1, wherein the variable reactive element is a variable inductor.

12. The tunable surface acoustic wave resonator of claim 11, wherein the variable inductor is a digitally controlled variable inductor.

13. The tunable surface acoustic wave resonator of claim 12, wherein the digitally controlled variable inductor comprises a bank of weighted inductors, each is series with a switch, the switch being configured to be in an ON state to include contribution to a total value of a variable inductance of the inductors in series with the switch or an OFF state to exclude or minimize contribution to the total value.

14. The tunable surface acoustic wave resonator of claim 1, wherein the planar metallic structure of the tuning electroacoustic transducer comprises:
a primary busbar coupled to the primary terminal;
primary fingers coupled to the primary busbar, the primary fingers being parallel to each other and being separated apart from each other by intervals corresponding to the acoustic wavelength at a resonant frequency;
a secondary busbar coupled to the secondary terminal; and
secondary fingers coupled to the secondary busbar, the secondary fingers being parallel to each other and being separated apart from each other by intervals corresponding to the acoustic wavelength at a resonant frequency,
wherein the primary fingers and the secondary fingers are interdigitated together and are separated apart from each other by intervals corresponding to one-half of the acoustic wavelength at a resonant frequency.

15. The tunable surface acoustic wave resonator of claim 1, wherein when the tuning electroacoustic transducer is on the exposed planar surface and the resonator IDT is at the buried planar surface.

16. The tunable surface acoustic wave resonator of claim 15, wherein the resonator IDT is aligned directly underneath the tuning electroacoustic transducer.

17. The tunable surface acoustic wave resonator of claim 1, wherein the resonator IDT is on the exposed planar surface and the tuning electroacoustic transducer is at the buried planar surface.

18. The tunable surface acoustic wave resonator of claim 17, wherein the tuning electroacoustic transducer is aligned directly underneath the resonator IDT.

19. The tunable surface acoustic wave resonator of claim 1, wherein
the high-acoustic-velocity substrate comprises silicon,
the intermediate layer comprises silicon dioxide, and
the piezoelectric layer comprises lithium tantalate.

20. The tunable surface acoustic wave resonator of claim 19, wherein the intermediate layer has a thickness of about 33.7% of the acoustic wavelength and the piezoelectric layer has a thickness of about 30% of the acoustic wavelength.

21. The tunable surface acoustic wave resonator of claim 20, being an incredible-high-performance (IHP) acoustic resonator.

22. A tunable bandpass filter comprising a plurality of interconnected surface acoustic wave resonators according to claim 1.

23. The tunable bandpass filter of claim 22, wherein the plurality of interconnected surface acoustic wave resonators comprise series connected tunable surface acoustic wave resonators and shunt connected tunable surface acoustic wave resonators.

24. The tunable bandpass filter of claim 22, exhibiting up to a 2% range of the tunable resonant center frequency when the variable reactive elements of the plurality of interconnected surface acoustic wave resonators comprise variable capacitors.

25. The tunable bandpass filter of claim 22, exhibiting up to a 20% range of the tunable resonant center frequency when the variable reactive elements of the plurality of interconnected surface acoustic wave resonators comprise variable inductors.

26. A tunable surface acoustic wave resonator comprising:
a substrate;
an intermediate layer on the substrate;
a piezoelectric layer on the intermediate layer, a combination of the piezoelectric layer and the intermediate layer forming a buried planar surface as an interface between the intermediate layer and the piezoelectric layer, the piezoelectric layer having an exposed planar surface opposite the buried planar surface;
a resonator on one planar surface among the buried planar surface and the exposed planar surface, the resonator comprising a resonator RF first terminal and a resonator IDT RF second terminal;
reflectors on the one planar surface, the reflectors flanking the resonator on the one planar surface;
a tuning electroacoustic transducer located, at least in part, on the other planar surface among the buried planar surface and the exposed planar surface, the tuning electroacoustic transducer including:
a tuning electroacoustic transducer primary terminal,
a tuning electroacoustic transducer secondary terminal,
a planar metallic structure between the primary terminal and the secondary terminal, the planar metallic structure having a placement on the other planar surface overlapping or underlying at least the resonator on the one planar surface, and
a variable reactive element electrically coupled across the tuning electroacoustic transducer primary and secondary terminals,
wherein the resonator and the reflectors are configured to form a resonant chamber within the piezoelectric layer that has a characteristic resonant center frequency when an RF input signal is applied across the resonator, whereby acoustic waves emanate away from the resonator through the piezoelectric layer, and
wherein tuning of the variable reactive element results in tuning the resonant center frequency.

27. The tunable surface acoustic wave resonator of claim 26, wherein the tuning of the variable reactive element comprises
changing a reactance of the variable reactive element added onto a native reactance of the plan metallic structure of the tuning electroacoustic transducer, resulting in changing a velocity and wavelength of the acoustic waves, and thereby changing the characteristic resonant center frequency and shifting in frequency the impedance-versus-frequency curve.

28. The tunable surface acoustic wave resonator of claim 26, further comprising reflectors on the other planar surface, the reflectors flanking the tunable electroacoustic transducer on the other planar surface.

29. The tunable surface acoustic wave resonator of claim 26, wherein the variable reactive element is on the other planar surface among the buried planar surface and the exposed planar surface.

30. The tunable surface acoustic wave resonator of claim 28, wherein the variable reactive element is located on a surface that is different from the other planar surface among the buried planar surface and the exposed planar surface.
